(19) United States
(12) Patent Application Publication
(10) Pub. No.: US 2026/0092959 A1
(43) Pub. Date: Apr. 2, 2026

(54) Transparent Induction Based D-Dot Electric Field Sensors

(71) Applicant: U.S. Army DEVCOM, Army Research Laboratory, Adelphi, MD (US)

(72) Inventors: David M. Hull, Adelphi, MD (US); David R. Allee, Phoenix, AZ (US); Kathleen P. Coleman, Columbia, MD (US); Sean M. Heintzleman, Silver Spring, MD (US)

(73) Assignee: U.S. Government, as Represented by the Secretary of the Army, Adelphi, MD (US)

(21) Appl. No.: 19/206,956

(22) Filed: May 13, 2025

Related U.S. Application Data
(60) Provisional application No. 63/646,436, filed on May 13, 2024.

(51) Int. Cl. G01R 29/08

(52) U.S. Cl. CPC G01R 29/0878; G01R 29/0871

(57) ABSTRACT

Exemplary transparent D-dot electric-field sensors are disclosed. Use of these exemplary devices enables combination with solar panels and other use cases previously impossible with prior metal plate style D-dot sensors. The transparent nature of these layers allows the sensor electrodes to be stacked with other optically sensitive electronics including photovoltaics. This doubles the available area for both functions, potentially doubling the output of both.

### RELATED APPLICATION DATA

This application claims benefit to U.S. Provisional Patent Application No. 63/646,4362 of the same title filed on May 13, 2024. The disclosure thereof is incorporated by reference herein its entirety for all purposes.

### GOVERNMENT INTEREST

The invention described herein may be manufactured, used and licensed by or for the U.S. Government.

### FEDERALLY SPONSORED RESEARCH OR DEVELOPMENT

Some research underlying this invention was made with government support under W911NF-20-2-0199, W911NF-15-2-0086 and W911NF-04-2-0005 awarded by the Army Research Laboratory.

### TECHNICAL FIELD

The present disclosure relates to sensors, and in particular to electric-field sensors.

### BACKGROUND

Electric-field (E-field) sensors are often built in one of two main types. The first type, potential gradiometers, sense a voltage between two electrodes connected to a high-impedance voltage preamplifier. In resistive media like soil or water, it is a relatively simple matter to make the sensor's input impedance (typically measured in MΩ) higher than the source impedance (typically measured in kΩ). These sensors are used in soil resistivity sensors, including “Meggers” and resistivity imaging systems, including those made by AGI SuperSting and Geometrics OhmMapper. For high-impedance sources like E-fields in air due to power lines, the source impedance is typically GΩ, so the sensor's input impedance must be much higher, up to TΩ. Such sensors have been built by Plessey and Quasar. Differential pairs of sensors can be used to measure the ambient electric field along the axis defined by the pair of sensors. One electrode can be grounded, or both electrodes can be electrically floating to create a “free body” sensor. Three such pairs of floating electrodes can be used to measure an ambient 3-D electric field.

The second main type of E-field sensors use electrode pairs with an input impedance that is low relative to the source impedance. The sensor effectively shorts the source E-field between the electrodes with a transconductance preamplifier. These sensors are sometimes called charge induction sensors or “D-dot” sensors because they measure the time-rate-of-change (dot) of the induced charge q, where q= [symbol] ρₛ= [symbol] D. The induced charge q is the induced charge density ρₛ integrated over the electrode area. The induced charge density on the (quasi-conducting) electrode surface is equal to the electric flux D. The output of the D-dot electrode is proportional to the induced current, i, flowing between the electrodes in response to a time-varying electric field:

$$i = \frac{dq}{dt} = kA \dot{D} , \qquad ( 1 )$$

where k is a geometric factor that accounts for field distortions like fringing and also variations in the flux density over the electrode surface, A is the area of the electrode, and \dot{D} is the time-rate of change of the electric flux D=εE. Since the output of this sensor is proportional to the electrode area, it is generally desirable to maximize this area. This type of E-field sensor is analogous to the more well-known search-coil magnetometer, or magnetic induction sensor, for measuring changing magnetic fields. D-dot sensors can be configured as “free-body” sensors, where both electrodes are electrically floating, or as ground-reference sensors, where one electrode is electrically grounded. D-dot sensors are also vector sensors; three orthogonal sensors can be used to measure 3-D electric fields (e.g., see U.S. Pat. No. 9,829,524).

D-dot sensors have several advantages relative to potential gradiometers. Most significantly, they are “low-impedance” sensors, so they are not affected by leakage currents flowing in dirty or poorly conducting surface films, etc. that could “short out” the high-impedance potential gradiometer. Second, they are also cheaper to manufacture, since they do not have to be built in ultra-low-humidity environments. Third, since the D-dot sensor will “short out” the ambient E-field, it will distort (typically enhance) the measured electric field; this field enhancement shows up in the k term in Eq 1. k is approximately 1.0 for flat thin sensors oriented perpendicular to the electric field, and is generally between 1 and 10 for convex shapes that result in fringing. Fourth, D-dot electrodes can be applied conformally to conducting surfaces (e.g., aluminum or carbon-fiber) airframes that would otherwise “short out” a potential gradiometer (e.g., see U.S. Pat. No. 7,411,401). A conformal D-dot electrode would normally be electrically isolated from the underlying conducting structure with a thin insulating layer.

Prior approaches for D-dot electric-field sensors have some limitations. First, the electrode sensitivity (that is, the output current relative to the applied E-field) is directly related to the electrode size, and so the available sensor area will limit the performance. This is especially true at low frequencies, since the sensitivity is also proportional to the frequency. Modern low-noise transconductance preamps have been developed for high-volume commercial markets, including mobile and wearable electronics, and these new ICs have improved the performance of all transducers with current outputs (including D-dot electrodes), but as sensors get smaller, transducer area remains a premium.

### SUMMARY OF THE INVENTION

The following summary of the invention is provided to facilitate an understanding of some of the innovative features unique to the present invention and is not intended to be a full description. A full appreciation of the various aspects of the invention can be gained by taking the entire specification, claims, drawings, and abstract as a whole.

We disclose novel transparent charge-induction based electric field sensors (also known as transparent D-dot electric-field sensors). Use of these exemplary devices enables combination with solar panels and other use cases previously impossible with prior metal plate style D-dot sensors. The transparent nature of these layers allows the sensor electrodes to be stacked with other optically sensitive electronics including photovoltaics. This doubles the available area for both functions, potentially doubling the output of both. These novel sensors provide compact, self-continued, self-powered, electric-field sensors.

According to embodiments, the transparent charge-induction based electric field sensor is generally formed of a transparent substantially non-conducting substrate; a transparent substantially conductive electrode grown on, adhered to, or placed on the transparent nonconducting substrate; and a circuit connected to the transparent substantially conductive electrode that is configured to measure current that is induced on the transparent non-conducting substrate to determine a sensed electric field.

The transparent substantially conductive electrode may be formed of indium tin oxide (ITO), indium-doped zinc oxide (IZO), nm-thick metallic films, iridium oxide, zinc oxide, carbon nanotubes, graphene, MXenes and other 2D materials, as a few non-limiting examples. Other transparent conductive material such as transparent conductive oxides, metallic nanowires, or any other transparent conducting material which is substantially transparent to light of one or more optical frequencies for energy harvesting or sensing might also be used. The resistivity of the transparent substantially conductive electrode may be on the order of kΩ to tens of MΩ at power frequencies, for example.

The transparent substantially non-conducting substrate may be formed of polycarbonate (PC), fluorinated ethylene propylene (FEP), perfluoro alkoxy (PFA), silicon oxide, polyethylene terephthalate (PET), polyimide, transparent oxides, transparent polymers, glass, as non-limiting examples. Other transparent non-conducting materials which are substantially transparent to one or more optical frequencies, or the top layer of a photovoltaic cell or optical sensitive layer may also be used. The resistivity of the transparent substantially non-conducting substrate may be at least 100 kΩ, but more preferably 1 MΩ or more. It should be several orders of magnitude greater than the transparent substantially conductive electrode, for example.

In some embodiments and implementations, the electrode and the substrate are less than or equal to about 1 mm in thickness in order to be flexible and conformal. Furthermore, the sensors may be further provided with a transparent protective coating and/or anti-static coating grown on, adhered to, or placed on the transparent substantially conductive electrode. The circuit can include an operational amplifier integrated circuit connected to the transparent substantially conductive electrode that is configured to operate as a transimpedance amplifier, to measure current that is induced on the transparent non-conducting substrate.

According to further embodiments, there is provided a system for electric field sensing and for energy harvesting or optical sensing. It may include a photovoltaic cell or optical sensitive layer; and a transparent charge-induction based electric field sensor. At least the substrate and transparent substantially conductive electrode are positioned on top of the photovoltaic cell or optical sensitive layer to permit light at one or more optical frequencies to substantially pass through the sensor to the photovoltaic cell or optical sensitive layer. The sensor may be preferably sized to cover up to 100% of the available area of the photovoltaic cell or optical sensitive layer useable for electric field sensing.

A method for layering a sensor is also provided. It includes providing a transparent charge-induction based electric field sensor; and coupling the sensor to a solar panel. The sensor is thus disposed between the solar panel and incoming light. Thus, it can measure the electric field without blocking the solar panel to frequencies useful for energy harvesting.

According to embodiments, there is a device provided for electric field sensing powered by EMF radiation across several spectra. It includes an EMF device or sensitive layer which is configured to absorb EMF radiation to output voltage; an optional transparent at the EMF radiation substantially non-conducting layer grown on, adhered to, or placed on the device or sensitive layer which is substantially transparent to light at one or more optical frequencies; a substantially conductive electrode transparent at the EMF radiation grown on, adhered to, or placed on the transparent non-conducting layer which is substantially transparent to light at one or more optical frequencies, wherein, in the presence of an electric field, the electric field induces an electrical current in the transparent substantially conductive electrode; and a circuit connected to the transparent substantially conductive electrode that is configured to measure current that is induced on the transparent non-conducting substrate to determine a sensed electric field. The EMF device or sensitive layer is configured to absorb one or more (i) visible light frequencies; (ii) IR light frequencies; UV light frequencies; (iii) RF frequencies; (iv) microwave frequencies; and/or (v) x-ray frequencies.

According to other embodiments, there is a device provided for electric field sensing powered by light in the optical spectra. It includes a photovoltaic cell or optical sensitive layer which harvests or senses light of one or more optical frequencies; an optional transparent substantially non-conducting layer grown on, adhered to, or placed on the photovoltaic cell or optical sensitive layer which is substantially transparent to light at one or more optical frequencies; a transparent substantially conductive electrode grown on, adhered to, or placed on the transparent non-conducting layer which is substantially transparent to light at one or more optical frequencies, wherein, in the presence of an electric field, the electric field induces an electrical current in the transparent substantially conductive electrode; and a circuit connected to the transparent substantially conductive electrode that is configured to measure current that is induced on the transparent non-conducting substrate to determine a sensed electric field.

If the surface of the photovoltaic cell or the optical sensitive layer nearest the transparent substantially conductive electrode is substantially conducting, then the transparent substantially non-conducting layer is present in the device. The device may further include a case of which at least a surface thereof is substantially transparent to light at one or more optical frequencies to permit light to enter and reach the photovoltaic cell or optical sensitive layer, as well as be transmitted from the optical sensitive layer.

In some embodiments and implementations, the transparent substantially conductive electrode may be transparent at one or more visible frequencies and acts as a dielectric at much higher operating frequencies. In others, the photovoltaic cell or optical sensitive layer and the battery may have a smaller area than the transparent substantially conductive electrode to permit light to pass therethrough. In yet others, the device may further include a battery and a power regulator circuit configured to control charging of the battery and manage energy use of the device by controlling voltage transfer between the battery, the photovoltaic cell and the device. And in others, the device may include one or more of the following: (i) a printed circuit board comprising electronic components; (ii) a display to emit light in one or more visible frequencies; (iii) an antenna to transmit/receive RF frequencies; (iv) a device or sensitive layer which is configured to absorb RF, microwave or x-rays to output voltage; (v) a lens, polarizer, and/or filtering layer; (vi) at least one coupling for a wired connection; or (vii) any combination thereof. The printed circuit board can be constructed to include an amplifier circuit; a microprocessor; a memory; the power regulator circuit; and communication means.

In certain embodiments, (i) the printed circuit board; (ii) the battery; (iii) the photovoltaic cell or optical sensitive layer; or (iv) any combination thereof, is/are substantially transparent to light at one or more optical frequencies. The electrode and/or the photovoltaic cell or optical sensitive layer can be comprised a plurality of pixelated elements to provide spatial resolution. The device may be constructed to be readily flexible or bendable for some application. For instance, the device may be judiciously configured to (i) mount to or be integrated into a vehicle; (ii) mount to or attach to a power transmission line; or (iii) mount to or attach to a structure which supports a power transmission line.

These and other embodiments of the invention are described in more detail, below.

### BRIEF DESCRIPTION OF THE DRAWINGS

The embodiments herein will be better understood from the following detailed description with reference to the drawings, in which:

FIGS. 1A, 1B and 1C show scenes including various transparent charge-induction based electric field sensors deployed according to embodiments of the invention.

FIGS. 2 and 2A-2J show schematics for various transparent charge-induction based electric field sensors according to embodiments of the invention configured to include a photovoltaic cell or optical sensitive layer which harvests or senses light of one or more optical frequencies.

FIGS. 3A-3D show schematics for various transparent charge-induction based electric field sensors according to embodiments of the invention configured to include an EMF device or sensitive layer which is configured to absorb EMF radiation to output voltage.

FIGS. 4A and 4B show exploded views of two transparent charge-induction based electric field sensors according to embodiments of the invention.

FIGS. 5A-5C show details of a printed circuit board, electronic circuits and a wiring diagram for the transparent charge-induction based electric field sensors according to embodiments of the invention.

FIG. 6A-6C shows plots for various conductive materials used as the transparent substantially conductive electrode of the transparent charge-induction based electric field sensor according to embodiments of the invention.

The foregoing and other objects, features, and advantages of the invention will be apparent from the following more particular description of preferred embodiments herein, as illustrated in the accompanying drawings in which like reference characters refer to the same parts throughout the different views. The drawings are not necessarily to scale, with emphasis instead being placed upon illustrating the embodiments, principles, concepts, etc. Certain inventive features are further provided through tables including design and analysis details as supported by the written description.

### DETAILED DESCRIPTION

The following description is of various exemplary embodiments only, and is not intended to limit the scope, applicability or configuration of the present disclosure in any way. Rather, the following description is intended to provide a convenient illustration for implementing various embodiments including the best mode. As will become apparent, various changes may be made in the function and arrangement of the elements described in these embodiments without departing from the scope of the present disclosure.

The following are definitions of terms used throughout the document:

An “electric field” is a low-frequency quasi-static field resulting from an electric charge. This charge may be changing or moving at non-relativistic speeds. Typical electric fields have a frequency below about 1 kHz. Unlike electromagnetic waves, a quasi-static electric field can exist with no significant or measurable magnetic field.

A “transducer,” “electrode, “charge collecting plate,” or “probe” refers to the charge-collecting front end of the sensor. In a “D-dot” E-field sensor, this part produces a small output current (such as 1 fA-10 μA) in response to a changing electric field.

A “transconductance preamplifier” is a device which converts the small current into a voltage signal that can be fed to a variety of processors or other electronics. This is used in charge-induction or “D-dot” E-field sensors.

“Optically sensitive layer” or “photosensitive layer” refers to a layer that is responsive to incoming and/or outgoing light at various wavelengths (e.g., 10¹²-10¹⁶ Hz), including IR, visible, and UV frequency bands, and sub-spectra thereof.

“RF sensitive layer” refers to a layer that is responsive to radio microwave, and X-ray frequencies, typically in the radio frequency band (100 kHz to 100 MHz) Microwave frequency band (100 MHz to 100 GHz), or X-ray frequency band ranges (10¹⁶ to 10²⁰ Hz), but not strictly limited to these bands.

The present disclosure presents the first demonstration of a transparent, charge-induction-based (D-dot) electric-field transducer layered on top of a commercially available solar panel. Traditional D-dot sensors use a relatively thick (>1 mm) metallic (highly conductive, non-transparent) electrode to collect charges induced from an electric-field source. The change in the charge with time is monitored as an induced current. The lack of transparency of this metallic electrode limits the use of D-dot sensors in low-size, weight and power (low-SWaP) Internet-of-Things (IoT) sensors and prevents D-dot electrodes from being used on top of optically sensitive layers as the D-dot electrode would block light to optical sensors, solar cells, or other optically sensitive layers. Therefore, the development of a transparent D-dot sensor based on transparent conductive materials allows for the combination of D-dot sensors with solar panels (or other optical sensitive devices) in a stack.

There is growing interest in self-powered sensors that can harvest energy from their environment. Solar panels are an obvious choice for sensors that are operated outdoors, but the output of these devices is also proportional to the available surface area. Therefore, it is highly desirable to create a device that can use the same physical area on a sensor for both sensing (specifically, electric-field sensing) and power harvesting (specifically, solar panels using PV cells). A useful figure of merit is the gain in power harvesting times the gain in D-dot sensor gain. Each function can have a gain of up to 2.0 if the full area is used instead at the same efficiency, instead of half of the total area for each function. We expect figures of merit greater than 1.0, and strive for figures of merit up to 4.0 for the two layers (optical and D-dot, for example) stack. If additional layers (optical, RF, and D-dot, for example) are included, it could surpass 4.0.

Embodiments of the invention uses the same physical area for two separate functions by making a transparent D-dot electric-field sensor the top layer, and an optically sensitive or RF-sensitive layer underneath. The same physical area limitation would also apply to multimodal sensors combing optically sensitive or RF-sensitive layers with the transparent D-dot sensor design. In all of these cases, “transparent” means that the high-frequency RF or optical energy needed by the under-layer is not impeded by the low-frequency D-dot sensor on the top layer. For solar energy harvesting applications, this means that the D-dot sensor layer should be transparent not only to visible light, but also to IR and/or UV wavelengths that contribute significant energy to the solar panel. For RF or IR sensing applications, this means that the D-dot layer acts as a dielectric at the RF or IR band(s) of interest.

Many solar panels have insulating (very high resistivity plastic or glass) surfaces with electrostatic properties which cause dust to collect on the panels. This dust blocks light and reduces the efficiency of the panels. Especially in very dry environments, the panels must be periodically cleaned, and this adds cost and risk to the operation of these panels. Therefore, it is highly desirable to add a transparent coating to a solar panel with dissipative properties that can reduce the electrostatic attraction of dust to the panel. Adding a transparent, resistive film that can function as a D-dot electrode can address both drawbacks. First, it can allow the same sensor real estate (physical area) to be used for both sensing and power harvesting functions, potentially doubling the total output of both (as addressed in the previous paragraph). Second, it can reduce the electrostatic attraction of dust to the solar panels, potentially increasing the output of the solar panel while reducing the maintenance requirements, especially in dry, dusty environments. This has the potential to increase the efficiency of the solar panels that could result in a figure of merit greater than 4.0 in some operating conditions. Accordingly, these improved approaches remain highly desirable.

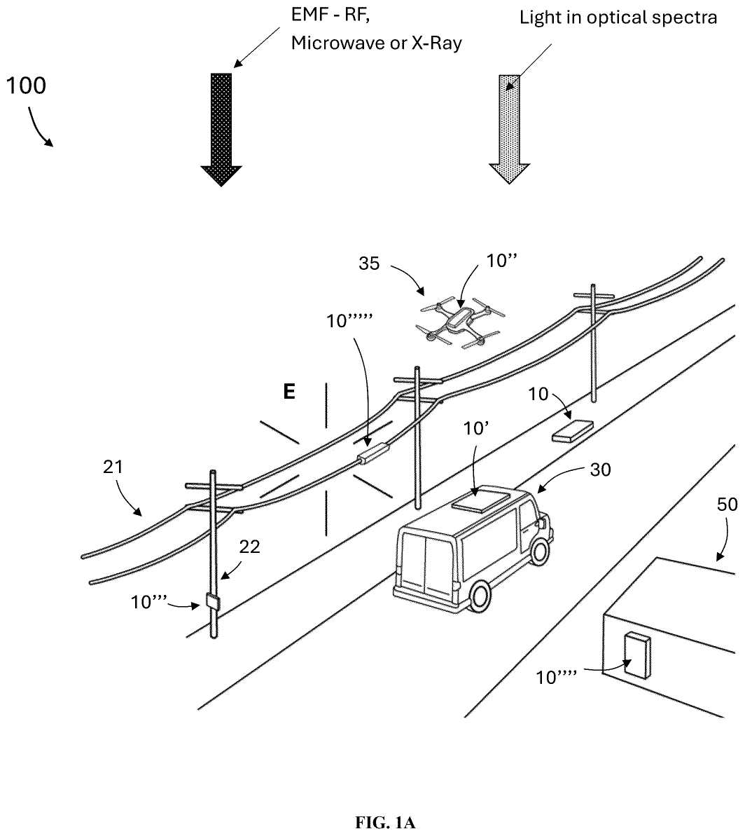

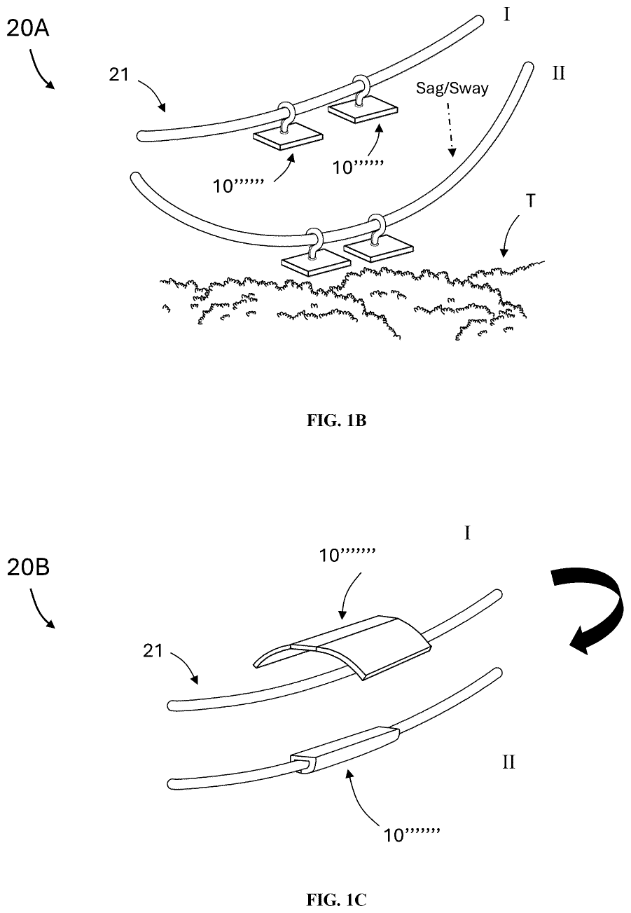

In accordance with various exemplary embodiments, with reference now to FIGS. 1 through 6, transparent D-dot electric field transducers use optically transparent and conductive materials to determine the changes in the magnitude and phase of electrical field signals. The optical transparency allows for novel applications and sensor system designs, where optically active materials including but not limited to sensors and energy harvesters, can be stacked below this electric-field sensor, reducing the overall surface area and making more compact design. Alternatively, the available surface area can be used for both functions and thus provide more E-field sensitivity and more power-harvesting capability in a given package.

FIGS. 1A, 1B and 1C show various transparent charge-induction based electric field sensors deployed according to embodiments of the invention. In scene 100 depicted in FIG. 1A, there are shown power lines 21. Power lines 21 carry high voltage across long distances. The power lines are held up with support structure, e.g., poles 22. As electrical power flows through power lines 21, an electric field E is generated which emanates from the power line in a generally perpendicular direction to the current flow. The transparent charge-induction based electric field sensors 10, according to embodiments of the present invention, are used to measure this electric field E. In addition to the electric field E, the scene 100 is subject to various electromagnetic force (EMF) energy, which may be ambient or artificial. For instance, the EMF energy may include light in the optical spectra. Such energy may be naturally produced by the sun or by other sources such as lighting. Other EMF energy may be present in the scene 100, such as RF requires, microwaves, x-rays and other radiation. The transparent charge-induction based electric field sensors 10 are further configured to harvest this energy for generating energy to power itself. That energy is harvested or sensed to generate a voltage which may power the sensor directly or be stored in a battery for future needs.

To sense the electric field, E, one or more transparent charge-induction based electric field sensors 10 may be used. As shown, the sensors can be placed in various locations. For instance, sensor 10 is positioned on the ground below the power lines 21. Sensor 10′ is mounted on the roof (or side) of a ground-based vehicle like a truck 30. This enables the truck to drive around different locations (and power lines) for rapid mobile detection and making electric field measurements. In a similar fashion, sensor 10″ is mounted on an aerial-based vehicle such as an airplane, helicopter, or UAV drone like quadcopter 35. The aerial-based vehicle may provide greater access to the power lines 21 by flying along them making electric field measurements.

Additional sensors may be mounted in other fixed positions relative to the power lines 21, such as sensor 10′″ mounted on pole 22, or sensor 10″″ mounted on a structure near the power lines like building 50, or sensor 10′″″ mounted directed on the power line 21 itself.

As shown in scene 20A in FIG. 1B, the sensors 10″″″ can have a hook to couple to hang from the power line 21. And as shown in scene 20B in FIG. 1C, sensors 10″″″ are configured to be readily flexible or bendable to wrap about the power lines comparing positions I and II there. In some embodiment, an aerial-based vehicle like quadcopter 35 could be used to install/uninstall sensors 10″″″ or 10″″″ onto the power lines 21. These power line mounted sensor embodiments may offer additional benefits as depicted in FIG. 1B. If the power lines 21 sag or sway, between positions I and II there they may approach fixed objects such as trees T. As the lines get closer to the objects, the detected electric field E will be attenuated due to the electric field E being absorbed and shorted through the objects. As such, the sensors may be used to detect sagging, damaged (downed), or swaying conditions in the power lines, such as when detected electric field abruptly changes.

By providing multiple measurements, using sensor 10 at different locations, more accurate electric field measurements may be made. The various sensors 10 may have communications means to transmit collected data to a server. Such data can be analyzed for many data points.

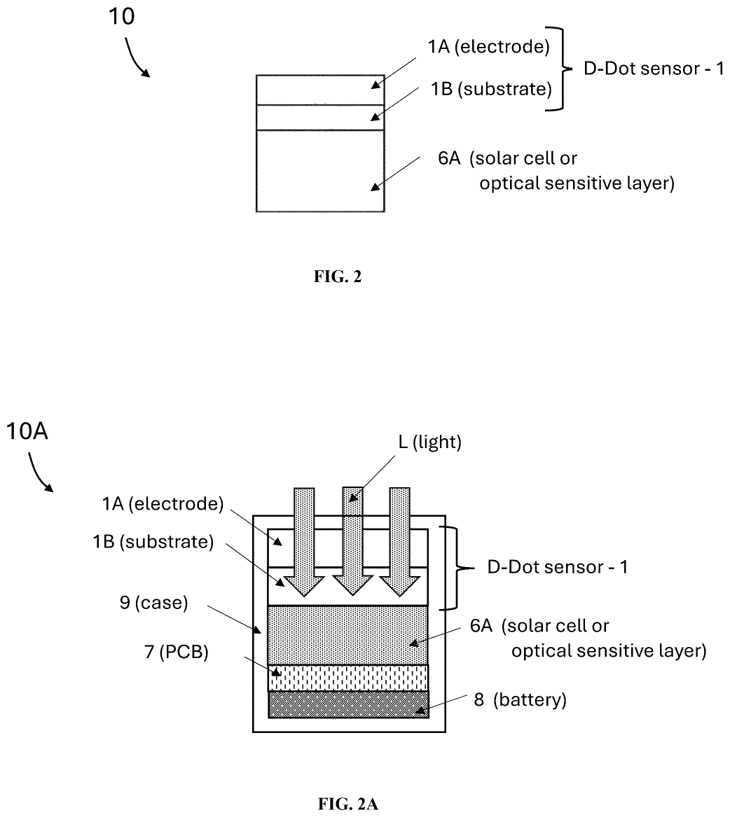

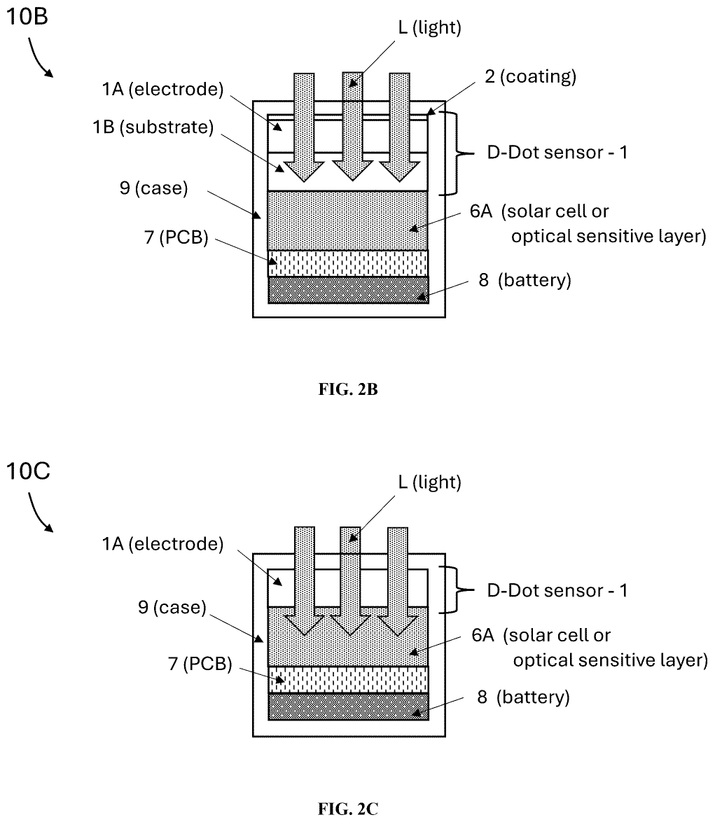

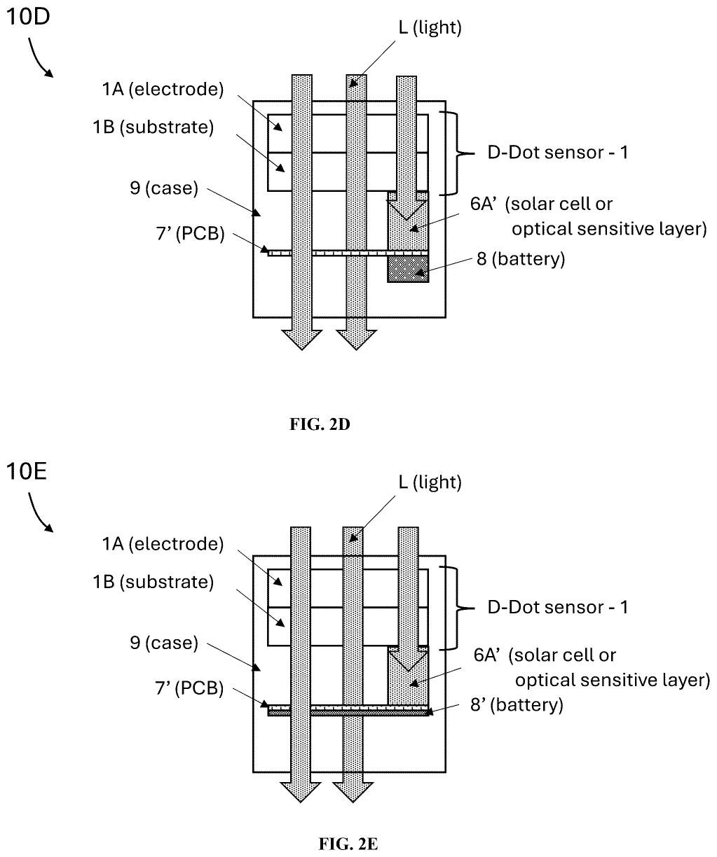

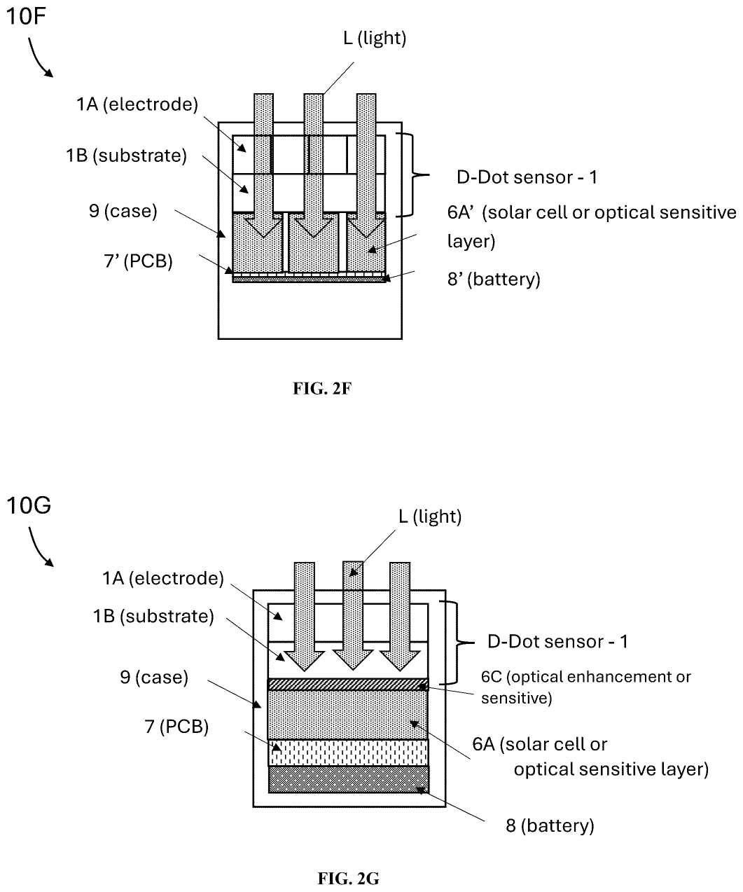

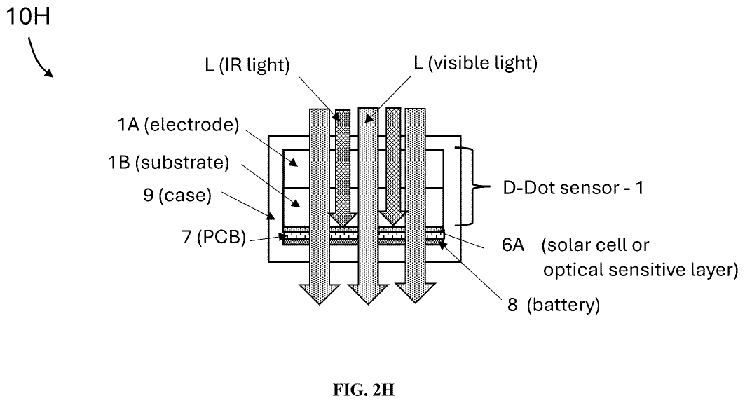

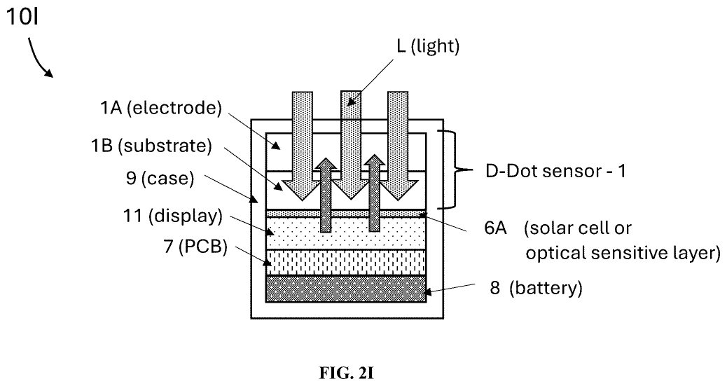

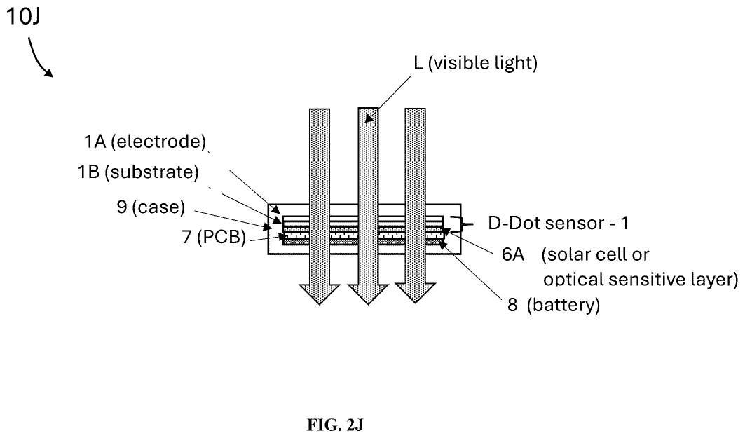

Additionally, in accordance with various exemplary embodiments, with reference to FIG. 2, the optical transparency of the D-dot plate could be used in or with a transparent housing around given electronics and thus outgoing light from internally optical signals can be readily transmitted. This may include small operational LEDs, MEMS corner reflectors modulating incoming light and communication allow for optical communications or communications in the frequency range where the incoming energy/signal must be transmitted in and out of the sensor.

D-dot electric-field sensors are based on charge induction, where the capacitance between two different conductors at different electrical potentials creates a charge separation on the two surfaces. Low-impedance D-dot sensors detect the time-rate-of-change in the induced charge, q, as an induced current, i, as shown in Equations 2.

$$\dot{D} ( t ) = \frac{dq}{dt} = i = kA εω \vert E \vert cos ( ω t + θ ) \qquad ( 2 )$$

where A is the electrode's area, k is a constant field enhancement factor that is generally between 1 and 10 and determined by the geometric configuration, ε is the permittivity of the medium between the electric field sources and the sensor (usually air, where ε is ˜8.859 pF/m), ω is the angular frequency of the electric field E (may be given as Volts per meter or V/m in SI units), and θ is the phase of the electric field. This equation implies that the field is sinusoidal. Alternatively, a non-sinusoidal field (and the sensor response to that field) can be expressed in terms of the sum of sinusoids at different frequencies.

For high sensitivity (i.e. larger dq/dt), the D-dot electrode (i.e. charge collecting plate) should be electrically conductive. Traditional D-dot sensors are based on metal electrodes that are opaque and thick (e.g., >1 mm). Generally, these opaque D-dot electrodes cannot be positioned on top of other layers like PV cells (or RF antennas), because that would block the light (or RF energy) from reaching layers under it. Likewise, D-dot electrodes cannot be under the photosensitive layers as the photosensitive layer will distort the incoming electric field. Therefore, prior D-dot sensors have not been layered on top of photosensitive materials that would be used for sensing and energy harvesting applications.

We note that the D-dot electrode 1A needs to be conductive enough that the current induced by the sensed electric field results in a negligible voltage drop across the electrode. In this invention, “conductors” can include “quasi-conductors” at low frequencies (as explained in John Kraus “12-4 Conductors and Dielectrics” in Electromagnetic 4^{th} Ed (1992) pp. 547-549). Specifically, there is negligible end-to-end voltage drop across the electrode when conducting (typically) pA of induced current due to a low-frequency source like a power line. Our electrodes function as “quasi-conductors” if the induced charge is proportional to the instantaneous E-field (at any point in time). In most of our use cases, the electrode can have MΩ of resistance with μV of voltage drop due to pA-level induced currents, so our quasi-conducting electrodes can act like perfect electric conductors.

Tradeoffs can also exist between conductivity and frequency response. The quasi-conducting transparent material will have both a series resistance ‘Rₛ’ to the induced currents flowing in the conductor, and a capacitance ‘C’ to grounded metals in its surrounding environment. This effectively creates a passive RC low-pass filter circuit with a corner frequency equal to 1/{2*pi*Rₛ*Cₑ}, meaning both the material properties and surrounding electronics will directly affect the frequency response of the D-dot transducer circuit. Most applications will have the quasi-conducting transparent material ‘stacked’ within 1 mm on top of a PCB with transimpedance amplifier of similar shape/size, so ‘Cₑ’ can be approximated as a parallel plate capacitor. Cₑ is proportional to the material's area ‘A’ but inversely proportional to the distance ‘d’ between the quasi-conducting transparent material and grounded PCB.

To make a credit-card-sized, solar-powered, flexible-D-dot sensor for measuring electric fields in the VLF spectrum, a transparent 100-nm thick material like Indium Tin Oxide (ITO) could be deposited on top of a 0.1-mm thick dielectric with a relative permittivity of about 4.5, e.g. FR-4 or glass. This means that Rₛ approximately equals 200 Ohm and Cₑ approximately equals 1.8 nF, creating a corner frequency of approximately 440 kHz. This D-dot electrode would conduct induced currents up to VLF frequencies (<30 kHz); however, it would conduct currents in higher frequencies of the RF spectrum (30 MHz-300 GHZ) very poorly. This would allow many RF antennae to still function when placed under this D-dot sensor itself, allowing the D-dot electrode to maintain a figure of merit (as defined in this patent) greater than 1.

Trade-offs can exist between conductivity (and upper frequency cutoff) and transparency. For example, if thin-film materials are not quite conducting enough for higher-frequency sensing applications, but if they are very transparent, we could make them thicker. Conversely, if a film has high conductivity (higher than needed) but low transparency, we may be able to make it thinner. The overall thickness of the D-dot electrode could be on the order of the thickness of a vinyl sticker (e.g., 2-4 mils, or 50-100 μm), or could be as thin as a decal. Standard decals are about 0.5 mil (13 μm) thick, and inkjet decals can be as thin as 3-5 microns (0.1 mil). Ultra-thin metal films could be as thin as 10 nm. Graphene nanofilms have been fabricated with thicknesses in the range of 1-100 nm (and in some cases, up to a few microns). ITO thin films are typically fabricated with thicknesses between 20 and 200 nm. Alternately, less-conducting transparent films could be as thick as needed, although if the sensor needs to be flexible, the max thickness may need to be kept below about 1 mm (1000 microns, or 40 mils). That range of thicknesses gives us a range of about 100,000:1 in conductivity (and frequency response) for a given material, and even greater ranges if we consider all available quasi-conducting transparent materials. Of course, this range may be less based on mechanical, or fabrication considerations associated with specific use cases.

While not limited to, this patent focuses on two classes of Internet of Things (IoT) sensor systems as examples for the subject invention. The first is on the order of the size of a deck of playing cards (˜6 cm wide×˜10 cm long×˜1 cm thick=˜60 cm³) and has an average power consumption of 10-30 mW. This class of sensor typically includes a battery with a capacity on the order of ˜10 W-hr. and so can run for 2-6 weeks without recharging. These batteries are commonly used in mobile phones and similar devices with higher power draws. If a ˜60 cm² solar panel is installed on the top of the sensor, this sensor can harvest ˜1 W peak, or ˜20-100 mW average in typical outdoor environments. When paired with the battery, this sensor can run continuously and indefinitely in many outdoor environments. Therefore, it is generally desirable to make the solar panel as large as possible so that the sensor can operate under a wider range of operating conditions. For electric-power sensing and anomaly detection applications (e.g., see U.S. Pat. No. 7,920,975), it is also desirable to make the sensing area as large as possible. This class of IoT sensors can be built with Commercial Off-The Shelf (COTS) solar panels, batteries, sensors, microcontrollers, printed-circuit boards, and packaging methods, where each major component in the sensor system is on the order of 1 mm thick.

A second exemplar class of IoT sensors is on the order of the size of a credit card (i.e., ˜5 cm wide×˜8 cm long×˜0.07 cm thick=˜3 cm³). To meet this size requirement, the D-dot electrode, solar panel, thin flexible PCB (with flexible electronics), thin-film battery, and a rubber or plastic coating for a housing must all be built with thicknesses on the order of 100 μm each. This sensor system can be constructed with COTS parts, although active research is ongoing to improve most of these thin-film system-level components. In this example, only ˜40 cm² of total surface area is available for both the solar panel and the D-dot sensor. This increases the desirability of using the same area for both functions.

Other use cases (besides self-powered electric-power sensing and/or anomaly sensing) may also increase the desirability of layering a transparent quasi-conducting D-dot electrode over a second functional layer. The optically sensitive under-layer could be a photodiode array or other device with sensitivity and/or resolution that is proportional to total area. It could be an indoor photovoltaic panel that can only harvest a few percent as much power as an outdoor solar panel of the same size; this increases the need to share available area even more. This under-layer could be an RFID tag or planar microwave antenna that also requires most or all of the available area. In this case, the D-dot electrode needs to be conducting enough that it acts like a perfect electrical conductor at electric-power frequencies but acts like a dielectric at much higher RF frequencies (typically 1-10 GHZ, and sometimes higher). In all of these cases, the D-dot electrode is “transparent” at the operating frequency band of the second layer. In other applications, large-area films could be used to turn a picture window (or a car windshield, or a mobile phone, or even a wall or other non-transparent surface) into a D-dot sensor. This larger area could provide exceptional sensitivity at low cost.

FIGS. 2 and 2A-2J show schematics for various transparent charge-induction based electric field sensors according to embodiments of the invention configured to include a photovoltaic cell or optical sensitive layer which harvests or senses light of one or more optical frequencies. Those figures show cross sections of the stacks of the transparent D-dot 1 stacked with solar cell or optically sensitive layer 6A and various other layers to create a sensor system. The same area used for the D-dot sensing application can also be used for solar energy harvesting, IR sensing arrays, optical displays, UV communications, etc. in layers under the D-dot electrode in the stack.

As initially shown in FIG. 2, exemplary embodiments of sensor 10 offer novel construction formed of D-Dot sensor 1 attached to, adhered to, or coupled to a solar cell of optical sensitive layer 6A. As compared to prior approaches, exemplary embodiments offer novel characteristics, including (1) transparent conductive materials being used to replace traditional opaque conductive materials in D-dot sensors (2) the ability to stack these D-dot sensors with solar panel or other photosensitive layers underneath them that outperforms separate D-dot electrodes and PV cells (or other energy harvesters), and (3) the thin and flexible and low size and weight nature of these film based D-dot sensors that permits sensor systems with total thickness <1 mm to be built using these films.

Accordingly, the D-Dot sensor 1 may be formed of a transparent substantially conductive electrode 1A and an optical transparent substantially non-conducting substrate 1B. If the surface of the photovoltaic cell or the optical sensitive layer 6A nearest the transparent substantially conductive electrode 1A is substantially conducting, then the transparent substantially non-conducting layer should be present in the sensor 10 to electrically isolate/decouple the electrode 1A from the solar cell of optical sensitive layer 6A. The substrate 1B may be provided to enable the material of the electrode 1A to more readily grow or adhere thereto compared to the top surface of the layer 6A.

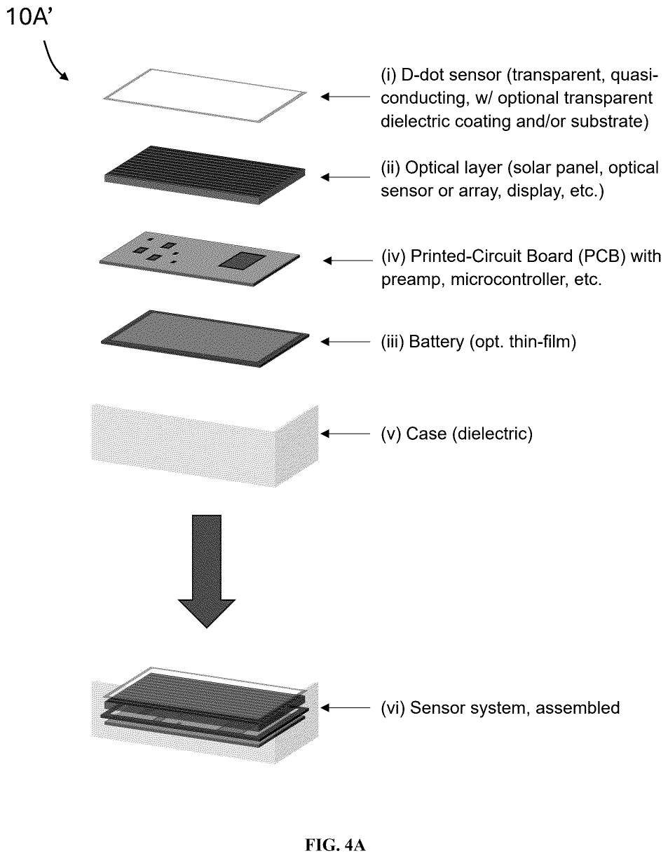

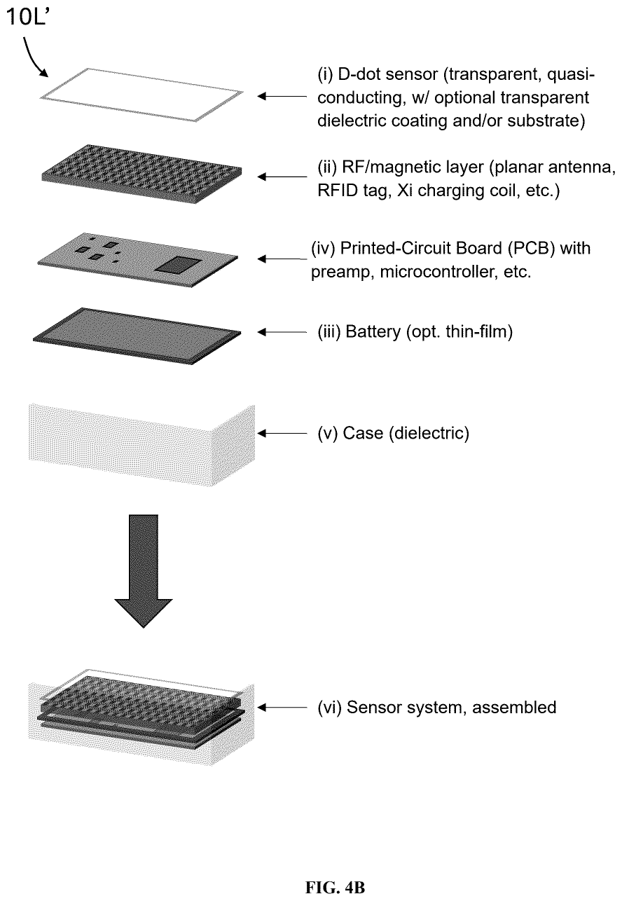

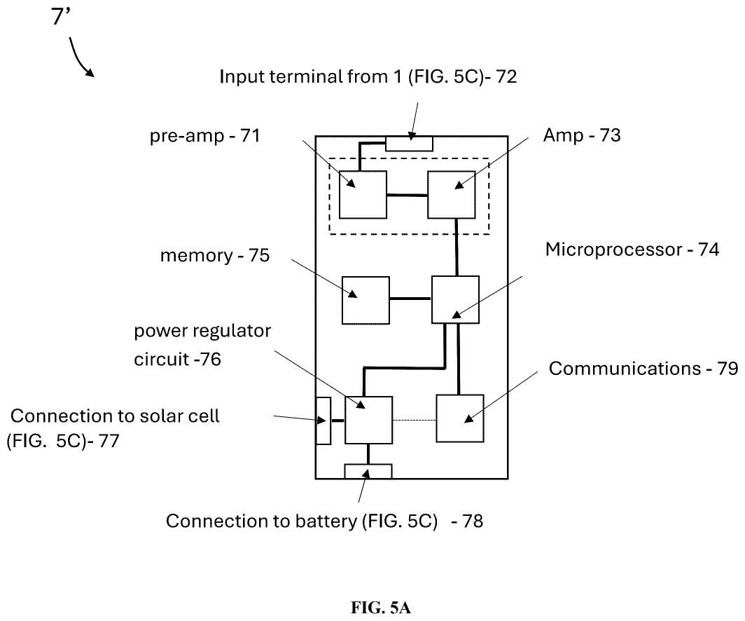

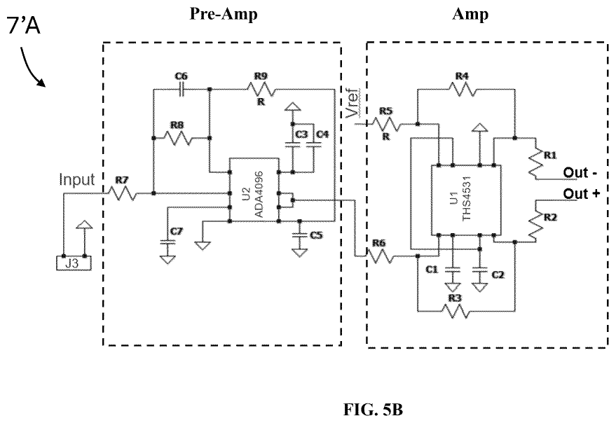

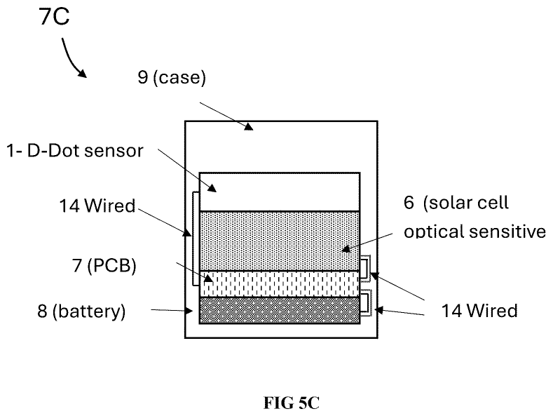

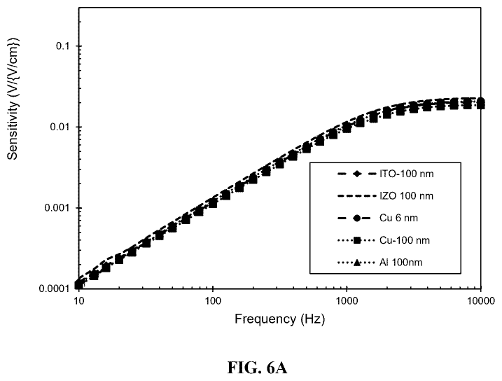

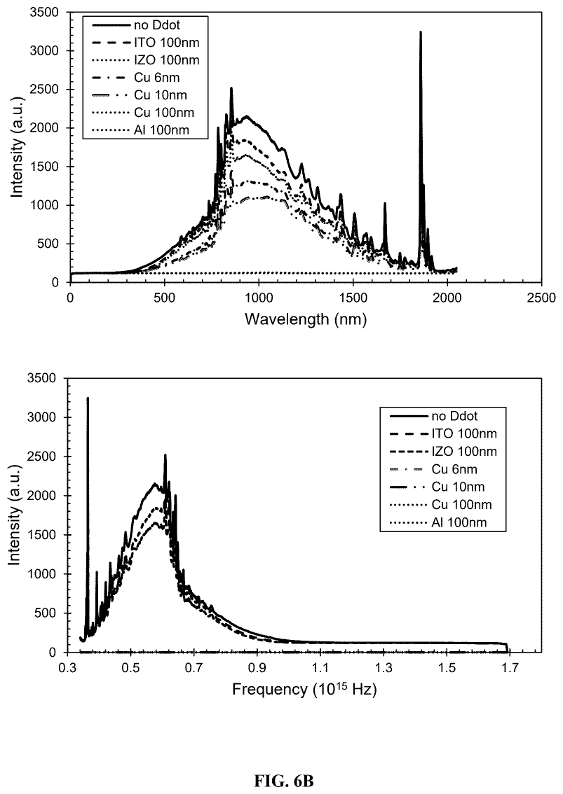

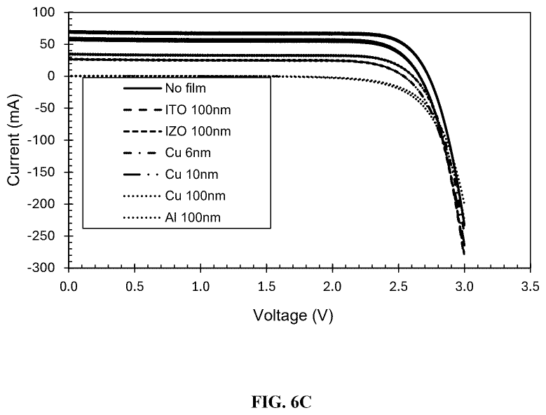

The transparent substantially conductive electrode 1A can use thin-film materials with high optical transparency, generally above 50% in the visible range (See FIG. 6), and that are electrically conductive enough to support the tiny currents induced by an external electric field (FIG. 5). These films may include indium tin oxide (ITO), indium-doped zinc oxide (IZO), nm-thick metallic films, iridium oxide, zinc oxide, carbon nanotubes, graphene, MXenes and other 2D materials, other transparent conductive oxide, metallic nanowires, or any material with >50% optical transparency at relevant wavelengths (such as but not limited to UV, visible, and IR) and electrically conductive. The films are grown on transparent substrates including, but not limited to polycarbonate (PC), fluorinated ethylene propylene (FEP), Perfluoro Alkoxy (PFA), silicon oxide, PET, polyimide, transparent oxides, transparent polymers, glass, or any other transparent nonconducting material configured to conduct induced currents. The films may be deposited via sputtering, evaporated, or plated, for example. For D-dot sensors, the input resistance of the electrode provides some ESD protection but should be small (typically tens of Ω to kΩ) compared to the impedance of the source field (typically GΩ for air E-fields and D-dot electrodes the size of typical IoT-class sensors), so that it effectively “shorts out” the input field. The feedback resistor sets the gain of the transconductance preamp and should be small compared to the input resistance of the op amp in the detection circuit (See FIG. 4).

The transparent substantially non-conducting substrate 1B, if present, may be formed of polycarbonate (PC), fluorinated ethylene propylene (FEP), perfluoro alkoxy (PFA), silicon oxide, polyethylene terephthalate (PET), polyimide, transparent oxides, transparent polymers, glass, as non-limiting examples. Other transparent non-conducting materials which are substantially transparent to one or more optical frequencies, or the top layer of a photovoltaic cell or optical sensitive layer may also be used. The resistivity of the transparent substantially non-conducting substrate may be at least 100 kΩ, but more preferably 1 MΩ or more. It should be several orders of magnitude greater than the transparent substantially conductive electrode, for example.

In some embodiments and implementations, the electrode 1A and the substrate 1B are each less than or equal to about 1 mm in thickness in order to be flexible and conformal. Furthermore, the sensors 10 may be further provided with a transparent protective coating and/or anti-static coating grown on, adhered to, or placed on the transparent substantially conductive electrode. The circuit can include an operational amplifier integrated circuit connected to the transparent substantially conductive electrode that is configured to operate as a transimpedance amplifier, to measure current that is induced on the transparent non-conducting substrate.

The solar cell of optical sensitive layer 6A harvests or senses light of one or more optical frequencies to generate a voltage. Such devices/layers exist. They can be configured to absorb one or more (i) visible light frequencies (ii) IR light frequencies; and/or (iii) UV light frequencies.

The solar cell is used for generating power for sensor 10. It may be used directly or stored in a battery (or other electrical storage device, like a rechargeable capacitor) for later use such as when it is night or otherwise dark.

FIG. 2A to 2J show more specific and detailed embodiments for sensor 10 for electric field sensing powered by light in the optical spectra. They show other elements. For instance, FIG. 2A, shows sensor 10A including transparent substantially conductive electrode 1A and transparent substantially non-conducting substrate 1B, forming D-Dot sensor 1, as well as a printed circuit board (PCB) 7, battery 8 and case 9. The PCB 7 includes the electrical components of the sensor 10 device, including a circuit connected to the transparent substantially conductive electrode that is configured to measure current that is induced on the transparent non-conducting substrate to determine a sensed electric field. More particularly, as later shown in FIG. 4, the PCB 7 may comprise: an amplifier circuit; a microprocessor; a memory; the power regulator circuit; and communication means. The PCB 7 may also include a power regulator circuit configured to control charging of the battery and manage energy use of the device by controlling voltage transfer between the battery, the photovoltaic cell and the device.

Light enters the top of device, passes though the transparent electrode 1A and transparent substate 1B to the solar cell or optical sensitive layer 6A. The solar cell or optical sensitive layer 6A makes use of light in one or more optical frequencies to generate power, or sense the incoming light, for example. So, the same area used for the D-dot sensing application can also be used for solar energy harvesting, photodetection, IR sensing arrays, optical displays, UV communications, etc. in the area under the D-dot electrode.

The case 9 holds all the elements of the sensor device. It may be formed of a non-conducting transparent material (similar to material of substate 1B) to enable light in the optical spectra to pass therethrough.

In these various exemplary embodiments, element the D-dot 1 charge collection plate which may be comprise of an electrode (1A) and a substrate layer (1A). The substrate layer can be optional if (1A) can be directly deposited or transferred on subsequent layers and the processing and deposition conditions are met. The D-Dot could be multiple pixels which will allow for higher spatial resolution of the electric field sensor 1 (6) solar cell or optical sensitive layer. This may include PV cells, sensors and photodiode, photodetectors. They may be various sizes and may be transparent to various wavelengths of light (6A′). They could be multiple pixels, which will allow for higher spatial resolution of the electric-field sensor. Multi optical sensors, photodiodes or solar cells could be combined in that layer to make a compact and dual-purpose layer. There may be multiple optical sensitive layers, which may include something like an optical enhancement layer such as a lens, polarizers, and/or filtering layer to enhance the signal to noise ratio of the bottom optical sensitive layer (6B′). The optical sensitive layer may include a light transmitter such as LED, pulse light sources, or display, which light is transmitted out of the device through the transparent D-Dot layer. This layer could also include an optical sensitive layer or a combination of RF sensitive layers (antenna or other RF emitters) with optical sensitive layers. (7) is the printed circuit board which will include power and signal condition circuitry. It may also include communications, microprocessors, memory, and additional sensors and features. It may be thin and transparent (7′) (8) is the battery or energy storage element to power the electronics.

Various exemplary embodiments have been tested and verified. For example, verification has been performed with various materials with optical transparency in the visible range (Sec FIG. 6). FIG. 6A shows the light intensity in the visible spectrum when there is no film in front of a photodetector. With the various films the light intensity is reduced, but still significant as these films are transparent in the visible regime. This means the photodetector, optical sensitive layers and solar cells still get sufficient light intensity (e.g., >50% of without a film) to operate. Conventional D-dot plates with thickness of 100 nm or greater of metals like copper (Cu) and aluminum (Al) do not allow any light to pass through meaning the optical layer would get no light intensity and cannot operate in a stacked configurations described by this patent.

Validation has compared its ability to detect electric fields with a controlled uniformed electric field source to a metallic based D-dot sensor with similar thickness. In order to observe improved sensor performance, the sensitivity of the D-dot sensor with a transparent electrode should generally be at least 50% of the sensitivity with a metallic one. In addition, the D-dot electrode should generally be at least 50% transparent. We demonstrated films from 50-90% transparent electrode that was placed above a solar panel (a optically sensitive device), and as expected, the solar panel's peak output current was 80% of what it is without the transparent D-dot sensor. This was verified on a small subset of transparent films with I-V curves of the solar panels (See FIG. 6B).

FIG. 2B shows sensor 10B further including a transparent optical coating 2 grown on, adhered to, or placed on the top surface of the electrode 1A. It may be a transparent protective coating and/or anti-static coating 2. This could be useful for applications where dust and/or particles accumulate on the surface and prevent light from entering the device. The use of the transparent conductive film on top of the solar panel may help reduce the buildup of dust on the solar panel. D-dot electrodes can be moderately resistive and still “short out” the ambient air E-field. There are several types of films that are moderately resistive; these films are also called dissipative or “anti-static” because they are sufficiently conductive to “bleed off” electrostatic charge before it can build up to levels that could result in ESD that might damage electronics, ignite combustible powders or vapors, etc. Some of these films are transparent at optical frequencies, so they can be layered on top of solar panels. In this way, a single surface can be used for two separate functions, both as an electric-field sensor and as an antistatic film that would reduce the buildup of dust on the solar panel. This provides improved performance with fewer (or possibly no) maintenance cleanings.

FIG. 2C shows sensor 10C where the top surface of the solar cell of optical sensitive layer 6A has a non-conducting surface. Thus, the transparent electrode 1A can be formed directly on cell/layer 6A which can eliminate need for a separate transparent substate 1B. That top surface effectively takes the place of and functions as the transparent substantially conductive electrode 1B. This is a great option as long as the processing conditions for 1A can be withstand by the subsequent layers.

FIG. 2D shows sensor 10D where the solar cell or optical sensitive layer 6A′ and battery 8 have a smaller footprint compared to the D-dot sensor 1 and the PCB 7′ is sufficient thin to allow some light pass. This is useful in cases where the entire case is also transparent so light can pass in and out both through the top and bottom and sides of the case 9.

FIG. 2E shows sensor 10E where the battery 8′ has a large footprint but it also sufficiently transparent. See, e.g., Sami Oukassi, Loic Baggetto, Christophe Dubarry, Lucie Le Van-Jodin, Séverine Poncet, and Raphaël Salot, “Transparent Thin Film Solid-State Lithium Ion Batteries,” ACS Applied Materials & Interfaces 2019 11 (1), 683-690, DOI: 10.1021/acsami.8b16364. This too useful in cases where the entire case is also transparent so light can pass in and out both through the top and bottom and sides of the case 9.

FIG. 2F shows sensor 10F where the electrode 1A of the D-dot 1 is configured as multiple pixel elements in the same layer. Sec, e.g., E. Chung, W. Ye, S. G. Vora, S. Rednour and D. R. Allee, “A Passive Very Low-Frequency (VLF) Electric Field Imager,” in IEEE Sensors Journal, vol. 16, no. 9, pp. 3181-3187, May 1, 2016. This would allow for higher spatial resolution of the electric field sensor. This could also apply for the optical sensitive layer. Multi optical sensors, photodiodes or solar cells could be combined in that layer to make a compact and dual-purpose layer.

FIG. 2G shows sensor 10G where there are multiple optical sensitive layers including optical enhancement or sensitive layer 6C. This layer could include optical elements like a lens, polarizing, and/or filtering layer to enhance the signal to noise ratio of the bottom optical sensitive layer 6A.

FIG. 2H shows sensor 10H where there are thin transparent solar cell/layer 6A, PCB 7 and battery 8. The solar cell/layer 6A can be configured to absorb at the IR frequencies and allow light through making the entire system transparent to most light frequencies.

FIG. 2I shows sensor 10I which includes a display 11. The display 11 can include an LCD, LED, O-LED display panel which can display information, such as the detected electric field, battery life, date/time, location data and/or other desired information. Because the electrode 1A and substate 1B are transparent, light emitted from the display 11 can pass also through,

FIG. 2J shows sensor 10J where all the thickness of all the element are minimized the to produce a very “thin” device (such as each less than 1 mm). This can enables a truly bendable or flexible device as shown in FIG. 1C.

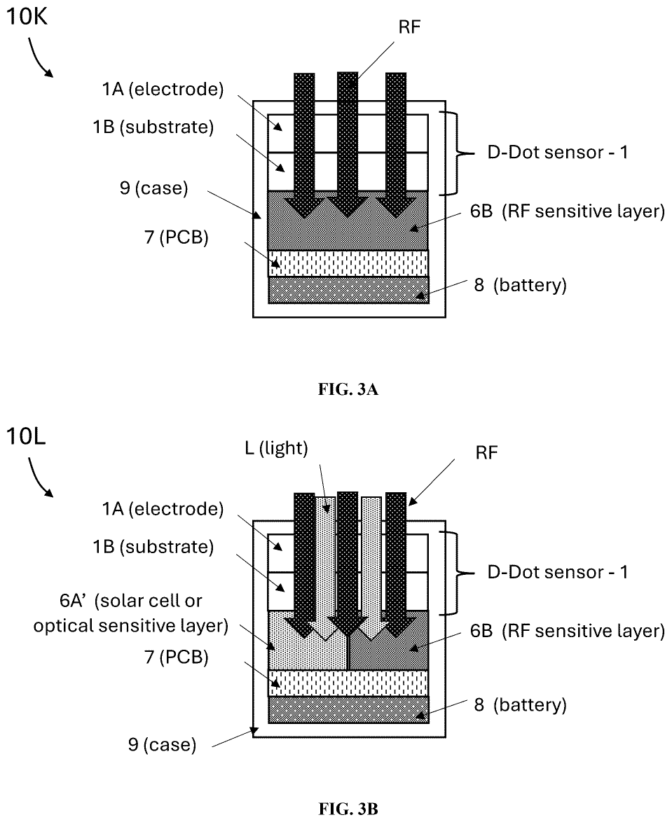

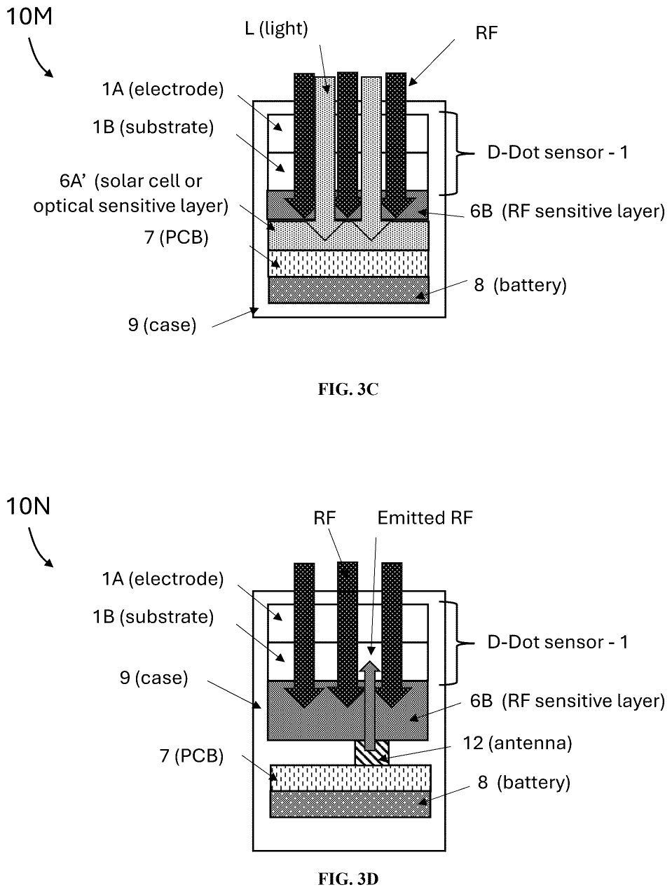

FIGS. 3A-3D show schematics for various transparent charge-induction based electric field sensors according to embodiments of the invention configured to include an EMF device or sensitive layer which is configured to absorb EMF radiation to output voltage. Those figures show cross sections of the stacks of the transparent D-dot 1 stacked with RF sensitive layers 6B and various other layers to create a sensor system.

FIG. 3A show sensor 10K, which is similar to FIG. 2A, with the photovoltaic cell or the optical sensitive layer 6A being replaced with a RF sensitive layer 6B. Alternatively, layer 6B could be any EMF device or sensitive layer which is configured to absorb EMF radiation to output voltage. Such devices/layers exist. They can be configured to absorb one or more (i) RF frequencies; (ii) microwave frequencies; and/or (iii) x-ray frequencies.

At low frequencies (generally, <1 MHz and typically, <100 kHz), the D-dot electrode can be conducting enough to act as an electric-field transducer, and resistive enough that it does not affect the (lower-impedance) magnetic fields. This is significant in the quasi-static regime, where the high-impedance electric field and the low-impedance magnetic field are generally independent of each other. In this way, a D-dot electrode may be put on top of a resonant magnetic induction energy harvester (e.g., like a Qi charger). The E-field sensor may be used on a robotic platform to find energized sources (for example, 60 Hz power, a 100-kHz Qi charger, or the like), and the Qi charger could be used to harvest energy. Alternately, a planar RF antenna operating in the microwave band could be placed under the D-dot electrode. Thus coil-based RFID tags, near-field comms, and Qi chargers (as specific examples) can be used in the same physical sensor area as the D-dot electrode.

FIG. 3B shows sensor 10L which combines an optical sensitive layer 6A being and a RF sensitive layer 6B. This enables harvesting in both optical and another EMF spectra. While the figure shows layers 6A and 6B side-by-side, FIG. 3C shows sensor 10M in which the layers could be stacked on top-of-one-another (such as layer 6A above layer 6B).

FIG. 3D shows sensor 10N which incorporates an antenna 12. Antenna 12 allows for the device to transmit and/or receive RF frequencies. The antenna can provide wireless communication means, such as configured for Blue-tooth, Near Field, of Wi-fi (IEEE 802.11).

FIGS. 4A and 4B show exploded views of two transparent charge-induction based electric field sensors 10A′ and 10L′ according to embodiments of the invention. The sensos are package in case 9. The case 9 can be a rigid housing, curved to other geometries (not necessarily box shape), or could be a conformal coating. This case may be transparent to the various EMF and the various components can be embedded in the casing as needed.

FIGS. 5A and 5C show details of a printed circuit board, electronic circuits and a wiring diagram for the transparent charge-induction based electric field sensors according to embodiments of the invention. The sensor system generally includes a sensor, power supply, processor, and storage or communications means. Communications may be wired such as UART, I²C, for example or wireless such as Wi-Fi, Bluetooth, or near field, for example. It may also include analog-to-digital converter(s) (ADC), a power-harvesting device, controls, connectors, display, enclosure, and possibly other common electrical circuit components, such as a pair of transducers (one may be grounded) and a preamp. It may also include filters.

FIG. 5A shows the top view of PCB 7′ which can include a pre-amp 71, amp 73, microprocessor 74, memory 75, power regulator circuit 76, connection to solar cell or optical sensitive layer 77, connection to battery 78 and communications 79. FIG. 5B shows a detailed circuit diagram circuit 7′A showing the pre-amp 71 and amp 73. Vref would be the board voltage which may be 3-5V, for example. The input connects to the D-dot charge collecting plates. The output connects to the microprocessor (such as FPGA, microcontrollers, ASIC, etc.), memory (such as EEPROM, FRAM, NVM, for example), or communication means to respond, record, or read the sensed data, for example. Other circuit designs might be used. Assuming an ideal amplifier, pre-amp 71 could be omitted in some embodiments

FIG. 5C shows a cross-section 7C of sensor showing the wired connections. The simplest method would be external wires running along the case. Wires can be soldered, adhered with Ag epoxy, ultrasonic solder techniques, or wire bonded for example. One wire connection to the D-dot to determine the change in E-field with reference to the ground plane in the PCB. The solar output or optical transparent layer may require a single wire 14 or multiple, as shown. If there is an energy harvester element, such as a solar cell, it would plug into a power conditioning circuit and then transfer to the battery. The battery would then also be connected to the PCB to power the D-dot circuit. Alternative energy storage devices may be used other than a battery. Data stored on the PCB may be locally stored, transmitted wirelessly or wired through the case.

FIG. 6A-6C shows plots for various conductive materials used as the transparent substantially conductive electrode of the transparent charge-induction based electric field sensor according to embodiments of the invention. The materials include: 100 nm ITO, 100 nm IZO, 6 nm copper, 10 nm Cu, compared to conventional metal layers (Cu 100 nm and Al 100 nm). FIG. 6A is a plot of sensitivity vs. frequency for those material. It shows the measured sensitivity of the D-dot made with various conductive materials. All conductive transparent films and have the same sensitivity in the quasistatic (“DC regime” from 10 Hz up to 10 kHz) as 100 nm Cu and 100 nm Al used in conventional D-dots. FIG. 6B are a plot of intensity vs. wavelength/frequency for various conductive materials used as the transparent substantially conductive electrode of the transparent charge-induction based electric field sensor according to embodiments of the invention. It noted that conventional D-dot plates of 100 nm or greater of metals like Cu and Al do not allow any light to pass through, meaning the optical layer would get no light intensity and cannot operate in a stacked configurations described herein. FIG. 6C is a plot of current vs. volage for various conductive materials used as the transparent substantially conductive electrode of the transparent charge-induction based electric field sensor according to embodiments of the invention.

Exemplary advantages of the transparent D-dot sensors disclosed herein include: (1) it can be stacked with photosensitive devices and layers including, but not limited to, solar panels and optical sensors; (2) it is thinner, and requires less material and weight compared to conventional D-dot sensors; (3) its transparency will allow for the D-dot electrode to allow internal optical signals to be transmitted and (4) when combined with a solar panel of the same size in a stack, we demonstrated a reduction in total surface area of 50% (traditional layouts would require the two to be side by side), with only a 20% reduction in performance of the solar panel, and only 30% reduction in the D-dot sensor's performance at 1 KHz. Further performance improvements are expected with more transparent and/or more conducting films. (4) The anti-static property of the transparent film may reduce dust accumulation on the solar panel by reducing cleaning and solar panel maintenance.

It will be appreciated that there is a slight reduction in the performance of the solar panel and the D-dot sensor compared to traditional setups. Exemplary embodiments may be utilized in connection with low-SWAP IoT sensor systems, electric-field sensing for commercial applications like detecting power-line fields, human machine interactions, electric-field sensors integrated on digital displays, and the like.

The use of transparent conductive films for D-dot sensor application is believed to be presented herein for the first time. This new stack setup will lead to new sensor system designs. The transparent D-dot electric-field sensor is based on transparent conductive films. These materials may be thin films allowing the electrode to be flexible and lightweight compared to relatively thick metallic electrodes used in conventional D-dot sensors. The transparency allows the D-dot sensor to sit on top of a solar panel, where the solar panel can harvest at least 50% of the available solar power without the D-dot sensor. A stack with the D-dot sensor on top of the solar panel ensures that the D-dot sensor has the maximum sensitivity, and the electric field signal is not distorted by any conducting materials sitting near the D-dot sensor's electrode. This leads to a 50% reduction in surface are required for a solar panel and D-dot sensor combination, or a doubling of sensor sensitivity over traditional methods. There is typically a finite amount of area available for the combination of the solar panel and (D-dot) sensor electrodes. Therefore, instead of only allocating some portion (say, 50%) to each function, the two devices can be stacked with 100% of the area, to provide greater performance for each function.

Beyond solar panels, the D-dot sensor can be placed above other optically sensitive materials where we demonstrated the optically sensitive layer will still receive >50% of incoming light at relevant wavelengths, allowing them to perform at >50% capacity. The reduction in size and weight, and unique optical properties of exemplary D-dot sensor designs will expand the use cases of these electric field sensors, for example in lower-SWaP IoT sensors both in defense and commercial applications.

In various exemplary embodiments, principles of the present disclosure can be utilized in connection with energy beaming lasers. The electric-field sensor may be used as a proximity sensor. By stacking the electrode and the laser receiver, improved performance of both functions is realized.

All patents, publications, and applications mentioned in the specification are incorporated herein by reference to the same extent as if each individual patent, publication, or application was specifically and individually incorporated herein by reference.

While the principles of this disclosure have been shown in various embodiments, many modifications of structure, arrangements, proportions, the elements, materials and components used in practice, which are particularly adapted for a specific environment and operating requirements may be used without departing from the principles and scope of this disclosure. These and other changes or modifications are intended to be included within the scope of the present disclosure and may be expressed in the following claims.

The present disclosure has been described with reference to various embodiments. However, one of ordinary skill in the art appreciates that various modifications and changes can be made without departing from the scope of the present disclosure. Accordingly, the specification is to be regarded in an illustrative rather than a restrictive sense, and all such modifications are intended to be included within the scope of the present disclosure. Likewise, benefits, other advantages, and solutions to problems have been described above with regard to various embodiments. However, benefits, advantages, solutions to problems, and any element(s) that may cause any benefit, advantage, or solution to occur or become more pronounced are not to be construed as a critical, required, or essential feature or element of any or all the claims.

As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. When language similar to “at least one of A, B, or C” or “at least one of A, B, and C” is used in the claims or specification, the phrase is intended to mean any of the following: (1) at least one of A; (2) at least one of B; (3) at least one of C; (4) at least one of A and at least one of B; (5) at least one of B and at least one of C; (6) at least one of A and at least one of C; or (7) at least one of A, at least one of B, and at least one of C.

1. A transparent charge-induction based electric field sensor comprising:
a transparent substantially non-conducting substrate;
a transparent substantially conductive electrode grown on, adhered to, or placed on the transparent nonconducting substrate; and
a circuit connected to the transparent substantially conductive electrode that is configured to measure current that is induced on the transparent non-conducting substrate to determine a sensed electric field.

2. The sensor of claim 1, wherein the transparent substantially conductive electrode comprises at least one of indium tin oxide (ITO), indium-doped zinc oxide (IZO), nm-thick metallic films, iridium oxide, zinc oxide, carbon nanotubes, graphene, MXenes and other 2D materials, other transparent conductive oxide, metallic nanowires, or any other transparent conducting material which is substantially transparent to light of one or more optical frequencies for energy harvesting or sensing.

3. The sensor of claim 1, wherein the transparent substantially non-conducting substrate comprises at least one of polycarbonate (PC), fluorinated ethylene propylene (FEP), perfluoro alkoxy (PFA), silicon oxide, polyethylene terephthalate (PET), polyimide, transparent oxides, transparent polymers, glass, any other transparent non-conducting material which is substantially transparent to one or more optical frequencies or the top layer of a photovoltaic cell or optical sensitive layer.

4. The sensor of claim 1, further comprising an operational amplifier integrated circuit connected to the transparent substantially conductive electrode that is configured to operate as a transimpedance amplifier, to measure current that is induced on the transparent non-conducting substrate.

5. The sensor of claim 1, where the electrode and the substrate are less than or equal to 1 mm in thickness in order to be flexible and conformal.

6. The sensor of claim 1, further comprising a transparent protective coating and/or anti-static coating grown on, adhered to, or placed on the transparent substantially conductive electrode.

7. The sensor of claim 1, where the resistivity of the transparent substantially conductive electrode is on the order of kΩ to tens of MΩ at power frequencies.

8. A system for electric field sensing and for energy harvesting or optical sensing comprising:
a photovoltaic cell or optical sensitive layer; and
a transparent charge-induction based electric field sensor according to claim 1, where at least the substrate and transparent substantially conductive electrode are positioned on top of the photovoltaic cell or optical sensitive layer to permit light at one or more optical frequencies to substantially pass through the sensor to the photovoltaic cell or optical sensitive layer.

9. The system of claim 8, where the sensor is sized to cover 100% of the available area of the photovoltaic cell or optical sensitive layer useable for electric field sensing.

10. A method for layering a sensor comprising:
providing a transparent charge-induction based electric field sensor according to claim 1; and
coupling the sensor to a solar panel,
wherein the sensor is disposed between the solar panel and incoming light.

11. A device for electric field sensing comprising:
an EMF device or sensitive layer which is configured to absorb EMF radiation to output voltage; and
an optional transparent at the EMF radiation substantially non-conducting layer grown on, adhered to, or placed on the device or sensitive layer which is substantially transparent to light at one or more optical frequencies;
a substantially conductive electrode transparent at the EMF radiation grown on, adhered to, or placed on the transparent non-conducting layer which is substantially transparent to light at one or more optical frequencies, wherein, in the presence of an electric field, the electric field induces an electrical current in the transparent substantially conductive electrode; and
a circuit connected to the transparent substantially conductive electrode that is configured to measure current that is induced on the transparent non-conducting substrate to determine a sensed electric field.

12. The device of claim 11, wherein the EMF device or sensitive layer is configured to absorb one or more (i) visible light frequencies; (ii) IR light frequencies; UV light frequencies; (iii) RF frequencies; (iv) microwave frequencies; and/or (v) X-ray frequencies.

13. A device for electric field sensing comprising:
a photovoltaic cell or optical sensitive layer which harvests or senses light of one or more optical frequencies; and
an optional transparent substantially non-conducting layer grown on, adhered to, or placed on the photovoltaic cell or optical sensitive layer which is substantially transparent to light at one or more optical frequencies;
a transparent substantially conductive electrode grown on, adhered to, or placed on the transparent non-conducting layer which is substantially transparent to light at one or more optical frequencies, wherein, in the presence of an electric field, the electric-field induces an electrical current in the transparent substantially conductive electrode; and
a circuit connected to the transparent substantially conductive electrode that is configured to measure current that is induced on the transparent non-conducting substrate to determine a sensed electric field.

14. The device of claim 13, wherein, if the surface of the photovoltaic cell or the optical sensitive layer nearest the transparent substantially conductive electrode is substantially conducting, the transparent substantially non-conducting layer is present in the device.

15. The device of claim 13, further comprising a case of which at least a surface thereof is substantially transparent to light at one or more optical frequencies to permit light to enter and reach the photovoltaic cell or optical sensitive layer, as well as be transmitted from the optical sensitive layer.

16. The device of claim 13, wherein the transparent substantially conductive electrode is transparent at one or more visible frequencies and acts as a dielectric at much higher operating frequencies.

17. The device of claim 13, wherein the photovoltaic cell or optical sensitive layer and the battery have a smaller area than the transparent substantially conductive electrode to permit light to pass therethrough.

18. The device of claim 13, further comprising: a battery and a power regulator circuit configured to control charging of the battery and manage energy use of the device by controlling voltage transfer between the battery, the photovoltaic cell and the device.

19. The device of claim 18, further comprising one or more of the following:
(i) a printed circuit board comprising electronic components;
(ii) a display to emit light in one or more visible frequencies;
(iii) an antenna to transmit/receive RF frequencies;
(iv) a device or sensitive layer which is configured to absorb RF, microwave or x-rays to output voltage;
(v) a lens, polarizer, and/or filtering layer;
(vi) at least one coupling for a wired connection; or
(vii) any combination thereof.

20. The device of claim 19, wherein the printed circuit board comprises: an amplifier circuit; a microprocessor; a memory; the power regulator circuit; and communication means.

21. The device of claim 19, wherein:
(i) the printed circuit board;
(ii) the battery;
(iii) the photovoltaic cell or optical sensitive layer; or
(iv) any combination thereof,
is/are substantially transparent to light at one or more optical frequencies.

22. The device of claim 13, wherein the electrode and/or the photovoltaic cell or optical sensitive layer comprises a plurality of pixelated elements to provide spatial resolution.

23. The device of claim 13, wherein the device is readily flexible or bendable.

24. The device of claim 13, wherein the device is configured to (i) mount to or be integrated into a vehicle; (ii) mount to or attach to a power transmission line; or (iii) mount to or attach to a structure which supports a power transmission line.
